(19) United States
(12) Patent Application Publication
(10) Pub. No.: US 2004/0224468 A1
(43) Pub. Date: Nov. 11, 2004

(54) Method for manufacturing a floating gate of a dual gate of semiconductor device

(76) Inventor: Sung-bo Hwang, Daejeon Metropolitan city (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/827,041

(22) Filed: Apr. 19, 2004

(30) Foreign Application Priority Data
May 7, 2003 (KR) 2003-29149

(51) Int. Cl. H01L 21/8238

(52) U.S. Cl. 438/264

(57) ABSTRACT

A method for manufacturing a low voltage semiconductor device by forming a floating gate of a nonvolatile memory device as a particulate layer and determining a memory state by control of three to four electrons per particle, and which can improve the reliability of the device with a reduction of the influence on the device by restricting the leakage caused by a local defective portion of a tunnel oxide film to only the particles on that portion. The disclosed method includes: forming a tunnel oxide film on a silicon substrate where a predetermined substructure is formed; forming a particulate layer on the tunnel oxide film layer; sequentially forming a control oxide film layer and a control gate layer on the dot layer; and forming a dual gate by patterning the control gate layer, the control oxide film layer, the particulate layer and the tunnel oxide film layer into a predetermined shape.

### BACKGROUND

1. Technical Field

A method for manufacturing a semiconductor device, which forms a floating gate in a dot shape before the formation of a dual gate of a semiconductor nonvolatile memory device.

2. Description of the Related Art

Generally, floating gates are used for storing charges to erase or delete data in memory devices of a nonvolatile metal oxide semiconductor (MOS) such as read only memories (ROM), erasable programmable read only memories (EPROM) and the like. One such conventional floating gate structure is shown in FIG. 1.

FIG. 1 is a cross sectional view for explaining a semiconductor device having a floating gate structure according to the prior art.

First, a tunnel oxide film layer 12, a floating gate oxide film layer 14, a control oxide film layer 16 and a control gate oxide film layer 18 are sequentially formed on a silicon substrate 10. Next, the control gate oxide film layer 18, the control oxide film layer 16, the floating gate oxide film layer 14, and the tunnel oxide film layer 12 are sequentially patterned into a predetermined shape by using a photographic process, thereby obtaining a floating gate structure shown in FIG. 1.

In order to form a thin film having the floating gate structure as shown in FIG. 1 and in order to collect electrons in the floating gate, a high voltage device is required. Further, in such a structure, even if only a single defective portion is generated in a tunnel oxide film 12, the electrons stored in the floating gate 14 all flow outward as leakage current thereby lowering the reliability of the device.

### SUMMARY OF THE DISCLOSURE

In consideration of the above problems associated with the prior art structure of FIG. 1, a method for manufacturing a semiconductor device is disclosed, which can produce a low voltage device by forming a floating gate for a nonvolatile memory device comprising a continuous layer of discreet particles and determining a memory state by control of three to four electrons per particle, and which can improve the reliability of the device by restricting the leakage caused by a defective portion of a tunnel oxide film to only the floating gate particles on that portion.

A disclosed method for manufacturing a semiconductor device comprises: forming a tunnel oxide film on a silicon substrate where a predetermined substructure is formed; forming a particulate layer on the tunnel oxide film layer that serves as a floating gate layer; sequentially forming a control oxide film layer and a control gate layer on the particulate layer; and forming a dual gate by patterning the control gate layer, the control oxide film layer, the particulate floating gate layer and the tunnel oxide film layer into a predetermined shape.

### BRIEF DESCRIPTION OF THE DRAWINGS

Other aspects of the present disclosure will become apparent from the following description of embodiments with reference to the accompanying drawings, wherein:

FIG. 1 is a cross sectional view showing a dual gate structure formed according to the prior art;

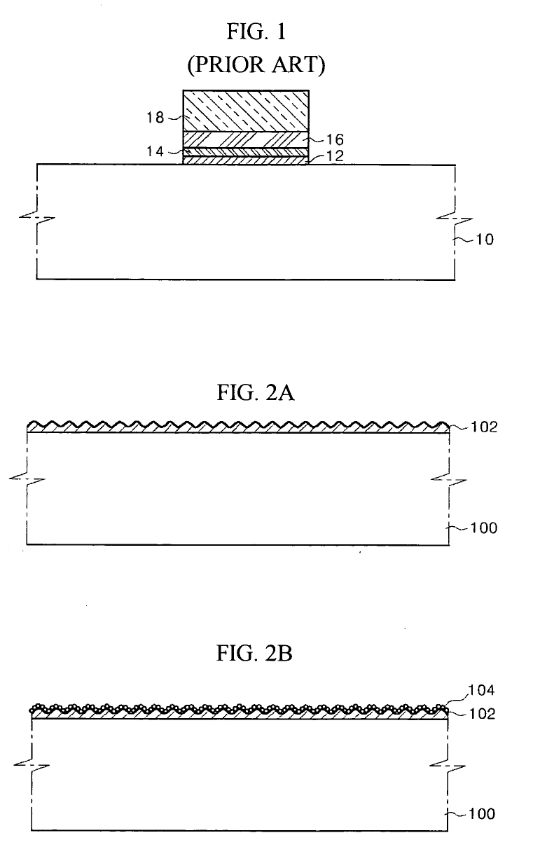

FIGS. 2 to 2e are cross sectional views showing a method for forming a dual gate structure according to a disclosed embodiment.

### DESCRIPTION OF THE PRESENTLY PREFERRED EMBODIMENT

Hereinafter, preferred embodiments will be described in greater detail in reference to the drawings. In addition, the following embodiments are for illustration only, not intended to limit the scope of this disclosure.

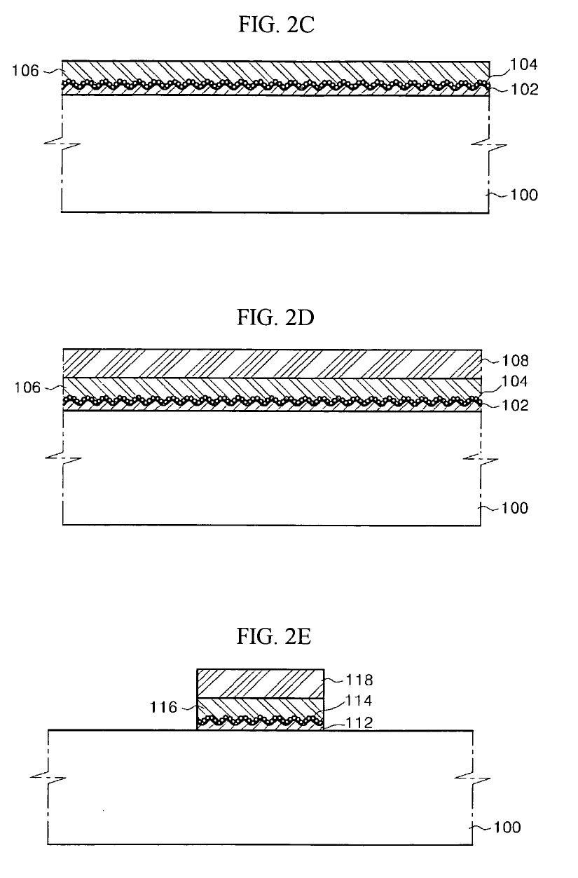

FIGS. 2a to 2e are cross sectional views showing a method for manufacturing a semiconductor device according to this disclosure.

First, as shown in FIG. 2a, a tunnel oxide film layer 102 with a rough surface is formed on a silicon substrate 100 having a predetermined substructure. According to a preferred embodiment, the tunnel oxide film layer 102 is formed by depositing SiO₂, which is formed by diffusing oxygen, or a material having a high dielectric constant on the silicon substrate 100.

Then, as shown in FIG. 2b, a particulate layer or dots or a dotted layer composed of silicon or silicon-germanium are formed on the tunnel oxide film layer 102 for the floating gate layer 104 by chemical mechanical deposition (CVD) with a particle size of approximately less than 60 nm in diameter or cross-section at a density of about 10¹¹ to 10¹² dots or particles per cm² to form a particulate floating gate layer 104. In case of forming a particulate layer from silicon-germanium, it is preferred that the concentration of germanium ranges from about 10 to about 20%.

According to an embodiment, a thin film for a floating gate can be formed into the tunnel oxide film layer 102 by using Ta₂O₅, HfO₂, and ZrO₂, etc. having a high dielectric constant. And, before forming a floating gate oxide film, a metal layer comprising Ta, Hf, Zr, and etc. can be deposited. Further, the particulate layer floating gate 104 may be formed by using a rapid thermal CVD method.

In the next step, as shown in FIGS. 2c and 2d, a control oxide film layer 106 and a control gate layer 108 are sequentially formed on the particulate floating gate layer 104. According to an embodiment, the control gate layer 108 is formed of a silicon-germanium thin film doped in-situ. Further, the control gate layer 108 can be formed of silicon or silicon-germanium.

Continuously, as shown in FIG. 2e, the tunnel oxide film layer 102, the particulate floating gate layer 104, the control oxide film layer 106 and the control gate layer 108 are sequentially patterned by an etching process such as lithography, thereby forming a dual gate provided with a floating gate 112, a dot floating gate 114, a control oxide film 116 and a control gate 118.

Furthermore, according to another embodiment, instead of formation by diffusing oxygen on a silicon substrate, a silicon oxide film is deposited by the CVD method, or an oxide film having a high dielectric constant such as Ta₂O₅, HfO₂, and ZrO₂, etc. is deposited by the CVD method. Next, a silicon or silicon-germanium compound is formed by the CVD method, and then can be formed into an oxide film such as Ta₂O₅, HfO₂, ZrO₂, etc., instead of a silicon oxide film, having a high dielectric constant and serving as a control oxide film.

As described above, by forming a floating gate in a particular layer 104 and inhibiting leakage current through the sides of the layer 104, the reliability of a device by preventing the degradation of the characteristics of the device due to only a single defective portion of the tunnel oxide film.

Furthermore, the present invention can provide low voltage device characteristics since three or four electrons per dot or particle enable a change in the memory state.

While the invention has been described in terms of preferred embodiments, those skilled in the art will recognize that the invention can be practiced with modification within the sprit and scope of the appended claims.

What is claimed is:

1. A method for manufacturing a semiconductor device comprising:
forming a tunnel oxide film on a silicon substrate where a predetermined substructure is formed;
forming a particulate layer on the tunnel oxide film layer;
sequentially forming a control oxide film layer and a control gate layer on the particulate layer; and
forming a dual gate structure by patterning the control gate layer, the control oxide film layer, the particulate layer and the tunnel oxide film layer into a predetermined shape.

2. The method of claim 1, wherein the particulate layer comprises silicon.

3. The method of claim 1, wherein the particulate layer comprises silicon-germanium.

4. The method of claim 1, wherein the particulate layer is formed with a particle size of less than or about 60 nm in diameter density ranging from about 10¹¹ to about 10¹² particles per cm².

5. The method of claim 1, wherein the particulate layer has a particle density ranging from about 10¹¹ to about 10¹² particles per cm².

6. The method of claim 1, wherein the particulate layer forms a floating gate of a dual gate structure.

7. The method of claim 1, wherein the tunnel oxide film comprises an oxide film having a high dielectric constant of Ta₂O₅, HfO₂, ZrO₂ and mixtures thereof.

8. The method of claim 1, wherein the tunnel oxide layer is fabricated from a material selected from the group consisting of Ta₂O₅, HfO₂, ZrO₂ and mixtures thereof.

9. The method of claim 1, wherein the particulate layer is formed by using a rapid thermal chemical mechanical deposition (CVD) method.

10. The method of claim 1, wherein the control gate layer is formed from a silicon-germanium thin film doped in-situ.

11. The method of claim 3, wherein, in the step of forming a silicon-germanium particulate layer, the concentration is germanium is ranges from about 10 to about 20 wt %.

12. A method for manufacturing a dual gate structure of a semiconductor device comprising:
forming a tunnel oxide film on a silicon substrate, the tunnel oxide film having a roughed upper surface;
forming a particulate layer on the roughed upper surface of the tunnel oxide film layer, the particulate layer serving as a floating gate layer;
sequentially forming a control oxide film layer and a control gate layer on the floating gate layer; and
forming a dual gate structure by patterning the control gate layer, the control oxide film layer, the floating gate layer and the tunnel oxide film layer into a predetermined shape.

13. The method of claim 12, wherein the floating gate layer comprises silicon.

14. The method of claim 12, wherein the floating gate layer comprises silicon-germanium.

15. The method of claim 12, wherein the floating gate layer is formed with a particle diameter or cross-section having an upper limit of about 60 nm.

16. The method of claim 15, wherein the floating gate layer has a particle density ranging from about 10¹¹ to about 10¹² particles per cm².

17. The method of claim 12, wherein the tunnel oxide film layer comprises an oxide file having a high dielectric constant and is selected from the group consisting of Ta₂O₅, HfO₂, ZrO₂ and mixtures thereof.

18. The method of claim 12, wherein the floating gate layer is formed using a rapid thermal chemical mechanical deposition method.

19. The method of claim 12, wherein the control gate layer is formed from a silicon-germanium thin film doped in-situ.

20. The method of claim 14, wherein the concentration of germanium in the floating gate layer ranges from about 10 to about 20 wt %.
